(19) United States
(12) Patent Application Publication
(10) Pub. No.: US 2026/0339348 A1
(43) Pub. Date: Oct. 29, 2026

(54) AUTONOMOUS CONVEYANCE VEHICLE

(71) Applicant: FUJI CORPORATION, Chiryu (JP)

(72) Inventors: Yoshihiro FUJITA, Chiryu-shi (JP); Shingo FUJIMURA, Toyoake-shi (JP)

(73) Assignee: FUJI CORPORATION, Chiryu (JP)

(21) Appl. No.: 19/121,172

(22) PCT Filed: Nov. 4, 2022
(86) PCT No.: PCT/JP2022/041145

§ 371 Date: Apr. 15, 2025

(51) Int. Cl. G05D 1/667; B65G 47/52; G05D 105/28

(52) U.S. Cl. CPC G05D 1/667; B65G 47/52; B65G 2203/0258; G05D 2105/28

(57) ABSTRACT

An autonomous conveyance vehicle is capable of conveying a conveyance object including an article used in a board work machine and a case configured to detachably hold the article, the autonomous conveyance vehicle including: a main body; a support section provided on the main body and configured to support the case; a detection section provided on the main body and configured to detect a presence or absence state of the article with respect to the case in conveyance of the conveyance object; and a determination section configured to determine whether attachment or detachment of the article with respect to the case has been performed based on a detection result by the detection section.

### TECHNICAL FIELD

The present description relates to an autonomous conveyance vehicle.

### BACKGROUND ART

In recent years, as part of labor-saving efforts, for example, as disclosed in Patent Literature 1, in an article conveyance system, conveyance of a conveyance object by an autonomous conveyance vehicle has been increasingly performed. In this case, the conveyance object is automatically conveyed by the autonomous conveyance vehicle in accordance with a conveyance plan set in advance, and automatic delivery of the conveyance object can be performed at a conveyance destination where the conveyance object has been conveyed.

Additionally, for example, as disclosed in Patent Literature 2, a part feeder that is a conveyance object may be conveyed using a cart that is detachably connected to an electronic component mounter. Here, a component monitoring system disclosed in Patent Literature 2 includes a monitoring device that determines whether a storage state of the part feeder has changed during a period from when the part feeder is loaded onto the cart to when the cart is connected to the electronic component mounter and that performs a warning operation in a case where the storage state of the part feeder has changed.

### CITATION LIST

### Patent Literature

Patent Literature 1: WO 2021/144866
Patent Literature 2: JP-A-2015-220304

### BRIEF SUMMARY

### Technical Problem

Regarding autonomous conveyance vehicles, efforts have been made to generalize the autonomous conveyance vehicles rather than specialize the autonomous conveyance vehicles, enabling the conveyance of various conveyance objects for more efficient operations. Incidentally, in production sites where various conveyance objects are conveyed by the autonomous conveyance vehicles, in principle, a worker does not accompany or monitor the conveyance process. For this reason, for example, regardless of intention or negligence, even in a case where attachment or detachment of an article that forms the conveyance object is performed during conveyance, determination can be made whether the attachment or detachment of the article has been performed only after the conveyance object has been delivered at the conveyance destination. In this case, the delayed determination may, for example, lead to a shortage of necessary components, potentially affecting production. Therefore, in the conveyance of the conveyance object by the autonomous conveyance vehicle, it is desired that the attachment or detachment of the article can be promptly determined.

An object of the present description is to provide an autonomous conveyance vehicle capable of detecting and determining attachment or detachment of an article in conveyance of a conveyance object.

### Solution to Problem

The present description discloses an autonomous conveyance vehicle capable of conveying a conveyance object including an article used in a board work machine and a case configured to detachably hold the article, the autonomous conveyance vehicle including: a main body; a support section provided on the main body and configured to support the case; a detection section provided on the main body and configured to detect a presence or absence state of the article with respect to the case in conveyance of the conveyance object; and a determination section configured to determine whether attachment or detachment of the article with respect to the case has been performed based on a detection result by the detection section.

### Advantageous Effects

With the autonomous conveyance vehicle, the detection section can promptly detect and determine the attachment or detachment of the article in the conveyance of the conveyance object.

### BRIEF DESCRIPTION OF DRAWINGS

FIG. 1 is a perspective view illustrating a production line including an autonomous conveyance vehicle.

FIG. 2 is a perspective view schematically showing the autonomous conveyance vehicle in a state in which a conveyance object is placed thereon.

FIG. 3 is a perspective view schematically showing a cart that is a main body of the autonomous conveyance vehicle.

FIG. 4 is a diagram illustrating detection by a detection section and notification to an outside.

FIG. 5 is a perspective view schematically showing an autonomous conveyance vehicle in a state in which a conveyance object is placed thereon, according to a first modification example.

FIG. 6 is a perspective view schematically showing a cart that is a main body of the autonomous conveyance vehicle, according to the first modification example.

FIG. 7 is an enlarged perspective view illustrating a configuration of a detection section of the first modification example.

FIG. 8 is a perspective view schematically showing an autonomous conveyance vehicle in a state in which a conveyance object is placed thereon, according to a second modification example.

FIG. 9 is a perspective view schematically showing a cart that is a main body of the autonomous conveyance vehicle, according to the second modification example.

FIG. 10 is a diagram illustrating detection by a detection section and notification to the outside, according to a third modification example.

### DESCRIPTION OF EMBODIMENTS

Hereinafter, an autonomous conveyance vehicle will be described with reference to the drawings. In the present embodiment, a case where the autonomous conveyance vehicle conveys a conveyance object necessary for production in a production line including a board work machine will be described as an example.

### 1. Outline of Production Line PL

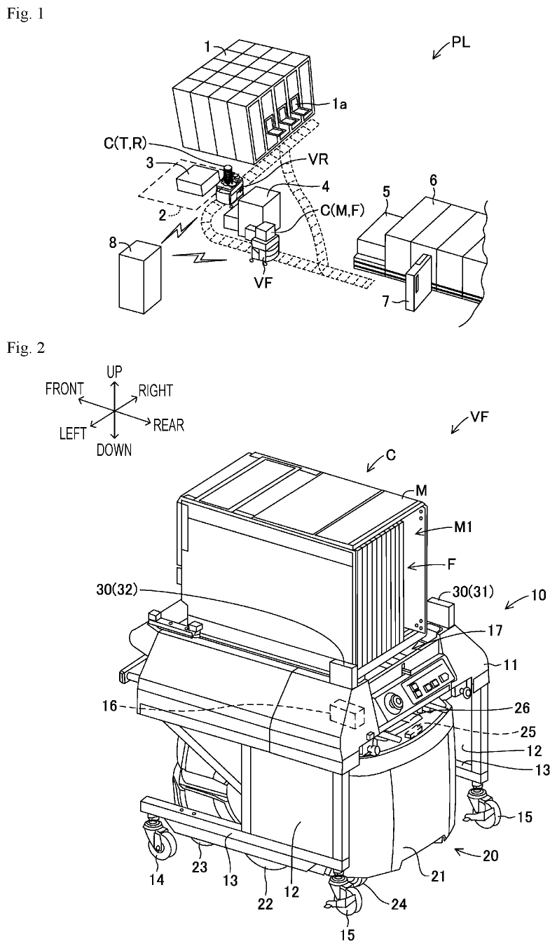

As shown in FIG. 1, production line PL includes warehouse 1, tape automatic processing device 3 installed in off-line setup area 2, reel loading device 4, and buffer station 5 and component mounter 6 as board work machines. In addition, production line PL includes reel conveyance vehicle VR and feeder conveyance vehicle VF as autonomous conveyance vehicles capable of conveying conveyance object C including an article used in component mounter 6 and a case that detachably holds the article. In production line PL, for example, the article (for example, a tape feeder or the like) conveyed (moved) to buffer station 5 by feeder conveyance vehicle VF is supplied to each of multiple component mounters 6 by loader 7. In the present embodiment, a case will be exemplified in which feeder conveyance vehicle VF conveys the article to buffer station 5, but feeder conveyance vehicle VF can also convey the article to component mounter 6.

Here, examples of the article used in component mounter 6 as the board work machine include a tape reel or a tape feeder that supplies an electronic component or the like to component mounter 6, and a suction nozzle that picks up the supplied component by suction. Other examples of the article include a mask in a case where the board work machine is a printing machine, and a tray or a board (workpiece). Additionally, examples of the case that forms conveyance object C include a rack for placing a tape reel, a suction nozzle, a mask, a board, or the like, a magazine that accommodates a tape feeder, and a pallet for placing a tray.

Reel conveyance vehicle VR conveys conveyance object C from entry/exit 1a of warehouse 1 to tape automatic processing device 3 installed in off-line setup area 2. In addition, reel conveyance vehicle VR conveys conveyance object C from tape automatic processing device 3 to reel loading device 4. Here, examples of conveyance object C conveyed by reel conveyance vehicle VR include tape reel R (hereinafter, simply referred to as “reel R”) that is an article placed on rack T which is a case.

Feeder conveyance vehicle VF conveys conveyance object C from entry/exit la of warehouse 1 to reel loading device 4. Additionally, feeder conveyance vehicle VF conveys conveyance object C from reel loading device 4 to buffer station 5. Here, examples of conveyance object C conveyed by feeder conveyance vehicle VF include tape feeder F (hereinafter, simply referred to as “feeder F”) that is an article accommodated in magazine M which is a case.

Reel conveyance vehicle VR and feeder conveyance vehicle VF, which are autonomous conveyance vehicles, can communicate with management device 8. Consequently, reel conveyance vehicle VR carries out rack T on which target reel R is placed, that is, conveyance object C, from entry/exit la of warehouse 1 and carries conveyance object C into tape automatic processing device 3 in accordance with a command based on a conveyance plan from management device 8. In addition, reel conveyance vehicle VR carries out rack T on which reel R, around which a carrier tape subjected to the necessary processing in tape automatic processing device 3 is wound, is placed, that is, conveyance object C, from tape automatic processing device 3 and carries conveyance object C into reel loading device 4.

Meanwhile, feeder conveyance vehicle VF carries out magazine M that accommodates target feeder F, that is, conveyance object C, from entry/exit la of warehouse 1 and carries conveyance object C into reel loading device 4 in accordance with a command based on the conveyance plan from management device 8. Additionally, feeder conveyance vehicle VF carries out magazine M that accommodates multiple feeders F loaded with reels R, that is, conveyance object C, from reel loading device 4 and carries conveyance object C into buffer station 5. Further, feeder conveyance vehicle VF carries out magazine M that accommodates feeder F after component supply or empty magazine M that does not accommodate feeder F as conveyance object C from buffer station 5 and carries conveyance object C into, for example, entry/exit la of warehouse 1.

Here, reel conveyance vehicle VR and feeder conveyance vehicle VF are different from each other in that reel conveyance vehicle VR conveys reel R placed on rack T as conveyance object C, whereas feeder conveyance vehicle VF conveys feeder F accommodated in magazine M as conveyance object C. However, reel conveyance vehicle VR and feeder conveyance vehicle VF have the same configuration. Therefore, in the following description, feeder conveyance vehicle VF will be specifically described as an example.

In the present embodiment, a case will be exemplified in which tape automatic processing device 3 and reel loading device 4 are disposed independently, but tape automatic processing device 3 and reel loading device 4 may be integrally provided. In this case, after the processing by tape automatic processing device 3, a loading process by reel loading device 4 is executed as is. Therefore, in production line PL, instead of including both reel conveyance vehicle VR that conveys only reel R placed on rack T as conveyance object C and feeder conveyance vehicle VF that conveys only feeder F accommodated in magazine M as conveyance object C, for example, feeder conveyance vehicle VF may be configured to also convey reel R placed on rack T as conveyance object C.

### 2. Feeder Conveyance Vehicle VF (Autonomous Conveyance Vehicle)

Next, a configuration of feeder conveyance vehicle VF exemplified as an autonomous conveyance vehicle will be described. As mentioned above, feeder conveyance vehicle VF automatically conveys magazine M in which feeder F is accommodated or which is empty as conveyance object C in accordance with the conveyance plan set in advance. The conveyance plan is set for each conveyance object C (specific feeder F and magazine M) conveyed by feeder conveyance vehicle VF based on a production plan set for production line PL. In the conveyance plan, the type and the number of feeders F to be accommodated in magazine M, the position of accommodated feeder F with respect to magazine M, that is, the state of magazine M to be conveyed, the conveyance path for conveying conveyance object C, the position (conveyance target) at which conveyance object C is to be loaded and unloaded, that is, conveyance object C is to be delivered, and the like are set in advance.

Meanwhile, in a case where feeder conveyance vehicle VF automatically (autonomously) conveys conveyance object C, there is a possibility that attachment or detachment of an unintended article, that is, an article that is not included in the conveyance plan, may be performed during conveyance, regardless of intention or negligence. For example, feeder F that should have been accommodated in magazine M may be forgotten to be accommodated, or feeder F that should not have been accommodated in magazine M may be accommodated. In this case, for example, the worker may accommodate correct feeder F in magazine M or take out incorrect feeder F from magazine M in the conveyance by feeder conveyance vehicle VF. However, since the insertion or removal of feeder F into or from magazine M is an act of restoring the correct state of magazine M based on the conveyance plan, the impact on production is minimal.

However, in a case where the insertion or removal of feeder F is performed in the conveyance of conveyance object C by feeder conveyance vehicle VF, even though the state of magazine M is correct with respect to the conveyance plan, for example, feeder F that is not included in the production plan may be erroneously added to and accommodated in magazine M, or correct feeder F may be taken out from magazine M. That is, when such attachment or detachment of the article is performed, the state of magazine M conveyed as conveyance object C by feeder conveyance vehicle VF is different from the state of magazine M set in advance in the conveyance plan.

Here, in a case where a determination about incorrect feeder F or the shortage of correct feeder F cannot be made in the conveyance of conveyance object C, for example, it is determined and discovered when conveyance object C has been conveyed (delivered) to buffer station 5. That is, since incorrect feeder F or the shortage of correct feeder F can be discovered at the conveyance destination where conveyance object C has been conveyed, it may take time to make the discovery, leading to a delay in discovery. Moreover, in a case where the discovery of incorrect feeder F or the shortage of correct feeder F is delayed, the state of magazine M is different from the conveyance plan, which may lead to, for example, production stops due to the component shortage in component mounter 6, or difficulties in tracking the whereabouts or origin of feeder F or components, thereby potentially affecting production.

Therefore, when the autonomous conveyance vehicle including feeder conveyance vehicle VF conveys conveyance object C, it is necessary to detect, determine, and monitor the attachment or detachment of the article even during conveyance. Then, in a case where the attachment or detachment of the article has been detected and determined in the monitoring, notification information for issuing a notification that the attachment or detachment has been performed is promptly output to management device 8, and for example, it is necessary to provide a notification to the worker or the manager via a display device or the like installed on production line PL. In a case where feeder F is attached to or detached from magazine M during conveyance, for example, accommodation (setup) of feeder F into magazine M is likely to be incomplete, resulting in a risk of feeder F falling out of magazine M during the conveyance operation by feeder conveyance vehicle VF.

In this regard, in the present embodiment, as shown in FIG. 2, feeder conveyance vehicle VF that is an autonomous conveyance vehicle mainly includes cart 10 as a main body, cart control section 16, traveling device 20, and detection section 30 that detects attachment or detachment (insertion or removal) of feeder F as an article to or from magazine M that is a case in the conveyance of conveyance object C. In the following description, as shown in FIG. 2, front and rear, left and right, and up and down of feeder conveyance vehicle VF are defined for convenience.

Cart 10 and traveling device 20 are configured to be substantially symmetrical with respect to a center line extending in a front-rear direction. Cart 10 that is the main body is coupled to traveling device 20 by a coupling mechanism (not shown). For example, traveling device 20 can enter an underside of cart 10 from behind, pull and move coupled cart 10, and exit from behind cart 10. Detection section 30 is provided on cart 10 that is the main body.

### 2-1. Cart 10

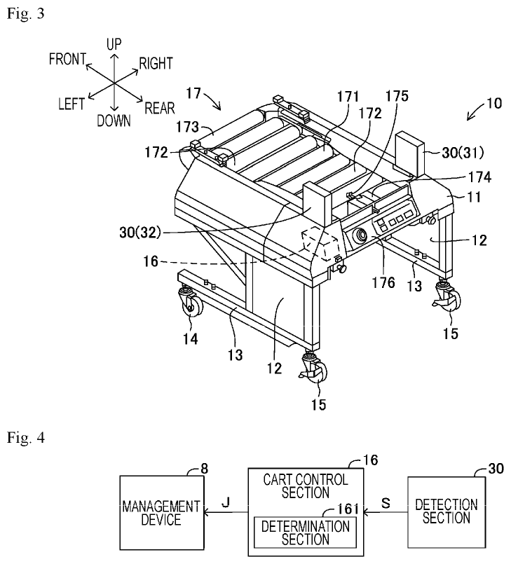

As shown in FIGS. 2 and 3, cart 10 mainly includes loading platform 11, left and right side surface portions 12, left and right leg portions 13, two front wheels 14 (only the left side is shown in FIG. 2 and the like), two rear wheels 15, and cart control section 16. As shown in FIG. 3, loading platform 11 is formed in a substantially rectangular shape in a plan view and is horizontally disposed to be spaced apart from a floor surface. Cart 10 that is the main body is provided with loading/unloading section 17 as a support section on an upper surface of loading platform 11, and detection section 30 is installed on a rear upper surface of loading platform 11 in the front-rear direction.

Left and right side surface portions 12 are provided to extend downward from a left edge and a right edge of loading platform 11. A space through which traveling device 20 enters is defined between left and right side surface portions 12 on the underside of loading platform 11. Left and right leg portions 13 extending in the front-rear direction are provided on respective undersides of side surface portions 12. A front lower part of leg portion 13 is provided with traveling front wheel 14, and a rear lower part of leg portion 13 is provided with traveling rear wheel 15. The total of four front wheels 14 and rear wheels 15 are free wheels whose traveling directions are variable. In addition, two rear wheels 15 are provided with stoppers.

### 2-2. Cart Control Section 16 (Determination Section 161)

Cart control section 16 is a microcomputer including CPU, ROM, RAM, and various interfaces as main components. Cart control section 16 executes various programs (not shown), thereby comprehensively controlling the operation of cart 10 (specifically, the operation of loading/unloading section 17 and the like).

In addition, as shown in FIGS. 1 and 4, cart control section 16 can communicate with management device 8. Further, cart control section 16 of the present embodiment includes determination section 161 and acquires detection result S output from connected detection section 30. Determination section 161 determines whether feeder F that is an article has been attached to or detached from (inserted into or removed from) magazine M that is a case has been performed based on detection result S by detection section 30. Then, cart control section 16 communicates with management device 8 and outputs notification information J regarding the insertion or removal (attachment or detachment) of feeder F to management device 8 in a case where determination section 161 determines the insertion or removal (attachment or detachment) of feeder F. As a result, in the present embodiment, management device 8 can promptly notify, for example, the worker, the manager, or the like of the insertion or removal (attachment or detachment) of feeder F.

In the present embodiment, a case will be exemplified in which determination section 161 is provided in cart control section 16. However, determination section 161 can also be provided in a control device (for example, traveling control section 25, which will be described below, or the like) other than cart control section 16, various computing devices, or the like. Additionally, determination section 161 can also be provided in management device 8 capable of communicating with cart control section 16. Further, determination section 161 can also be formed on a cloud.

### 2-3. Loading/Unloading Section 17 (Support Section)

Loading/unloading section 17 loads and unloads magazine M in which feeder F is accommodated or which is empty from a front surface of cart 10 on the front side in the front-rear direction. As shown in FIG. 3, loading/unloading section 17 includes main roller 171, six drive rollers 172, guide roller 173, locking mechanism 174, locking hook 175, operation panel 176, a drive motor (not shown), and the like. The three types of rollers are columnar or cylindrical members extending in the left-right direction and are supported to be rotatable around their central axes. Guide roller 173, three drive rollers 172, main roller 171, and three drive rollers 172 are disposed in this order from the front side to the rear side of cart 10.

Main roller 171 is driven by forward rotation and reverse rotation of the drive motor and rotates in a forward direction and a reverse direction. Six drive rollers 172 are coupled to main roller 171 by a transmission belt (not shown) and rotate in the same rotation direction and at the same rotation speed as main roller 171 in synchronization. Guide roller 173 can rotate freely without any applied driving force. Magazine M (conveyance object C including rack T and the like) is loaded by the rotation of main roller 171 and drive rollers 172 in the forward direction, and magazine M (conveyance object C including rack T and the like) is unloaded by the rotation in the reverse direction. The control of driving and stopping of the drive motor and the control of the rotation direction are performed by cart control section 16.

Locking mechanism 174 is disposed behind rearmost drive roller 172. Locking mechanism 174 locks loaded magazine M (conveyance object C including rack T and the like) using locking hook 175. As shown in FIG. 3, a front side of locking hook 175 is bent upward, and locking hook 175 is supported to be swingable in an up-down direction using an elastic member.

Consequently, when magazine M (conveyance object C including rack T and the like) is loaded, locking hook 175 temporarily descends and then rises, thereby automatically locking a locked portion (not shown) provided at a rear end of magazine M (conveyance object C including rack T and the like). Alternatively, locking hook 175 temporarily descends and then rises, thereby automatically fitting into a locked hole provided at the rear end of magazine M (conveyance object C including rack T and the like). On the other hand, immediately before magazine M (conveyance object C including rack T and the like) is unloaded, locking hook 175 is driven downward, for example, by an electromagnetic solenoid (not shown), to release magazine M (conveyance object C including rack T and the like) from the locking. In this case, the operation of the electromagnetic solenoid is controlled by cart control section 16.

As mentioned above, the loading/unloading operation of loading/unloading section 17 is automatically performed mainly under the control of cart control section 16. In addition, by operating operation panel 176 disposed at a rear part of loading platform 11, the manual operation for some of the operations of loading/unloading section 17 is possible. Specifically, by operating operation panel 176, for example, in a case where loading/unloading section 17 stops due to an abnormality (error) in the loading/unloading operation, that is, in a case of a so-called error stop, it is possible to release the error or perform an emergency stop of loading/unloading section 17. Here, in order for loading/unloading section 17 to perform a stable loading/unloading operation, it is important that feeder conveyance vehicle VF, more specifically, cart 10, is conveyed (moved) along a conveyance path set by the conveyance plan set in advance, stops precisely at a stop position, and faces the conveyance destination that is a conveyance target at the stop position.

Here, cart 10 includes a power receiving connector (not shown) on loading platform 11. The power receiving connector is disposed, for example, on a bottom plate of loading platform 11, that is, to face traveling device 20 that has entered the space formed between left and right side surface portions 12. Consequently, in a case where cart 10 and traveling device 20 are coupled to each other, the power receiving connector is fitted to a power supply connector (not shown) provided on traveling device 20 side. The power supply connector is connected to a battery (not shown) incorporated into traveling device 20. Therefore, by fitting the power receiving connector on cart 10 side to the power supply connector on traveling device 20 side, power for driving cart control section 16 and loading/unloading section 17 is supplied from the battery on traveling device 20 side. That is, there is no need to provide a battery on cart 10 to supply power for driving cart control section 16 and loading/unloading section 17.

In cart 10, a coupling mechanism for coupling with traveling device 20 that has entered the space formed between left and right side surface portions 12 is provided for the bottom plate of loading platform 11. Additionally, in cart 10 a positioning mechanism (bumper) that enables positioning of cart 10, that is, feeder conveyance vehicle VF, during the loading or unloading of conveyance object C is provided for a front part of loading platform 11. Since configurations and operations of the coupling mechanism and the positioning mechanism are not directly related to the present embodiment, descriptions thereof will be omitted.

### 2-4. Traveling Device 20

As shown in FIG. 2, traveling device 20 includes device main body 21, pair of left and right drive wheels 22 (only the left side is shown in FIG. 2), pair of left and right front wheels 23 (only the left side is shown in FIG. 2), pair of left and right rear wheels 24 (only the left side is shown in FIG. 2), traveling control section 25, operation panel 26, a traveling motor (not shown), and the like. Device main body 21 has a substantially elongated rectangular parallelepiped shape in the front-rear direction and is formed in a shape having four rounded corners in a plan view. Device main body 21 is horizontally disposed to be slightly spaced apart from the floor surface.

Drive wheel 22 is disposed at an intermediate position in the front-rear direction on the underside of device main body 21. Each of drive wheels 22 is driven by forward rotation and reverse rotation of the traveling motor controlled by traveling control section 25. Drive wheels 22 can rotate at different rotational speeds or in different rotational directions from each other. As a result, traveling device 20 can freely move forward and backward and change directions.

Front wheel 23 is disposed at a position in front of drive wheel 22 in the front-rear direction on the underside of device main body 21. Rear wheel 24 is disposed at a position behind drive wheel 22 in the front-rear direction on the underside of device main body 21. The total of four front wheels 23 and rear wheels 24 are free wheels whose traveling directions are variable. Front wheels 23 and rear wheels 24 are driven to rotate following the rotation state of each of drive wheels 22. The distance between the left and right wheels, that is, the tread width, is, for example, the maximum at drive wheels 22, the minimum at front wheels 23, and an intermediate value at rear wheels 24. In this manner, since the tread width of drive wheels 22 is the maximum, excellent steering performance of traveling device 20 is ensured.

Traveling control section 25 is a microcomputer including CPU, ROM, RAM, and various interfaces as main components. Traveling control section 25 executes various programs (not shown), thereby comprehensively controlling the operation of traveling device 20 (specifically, operations such as driving, stopping, and rotation directions of the traveling motor).

In addition, as shown in FIG. 1, traveling control section 25 can communicate with management device 8. Consequently, traveling control section 25 can control the traveling of traveling device 20 in accordance with the conveyance path and the conveyance target set by the conveyance plan through communication with management device 8. Further, traveling control section 25 can communicate with cart control section 16 in a state in which cart 10 and traveling device 20 are coupled to each other. As a result, cart control section 16 can acquire various information regarding traveling (movement) including the positions of feeder conveyance vehicle VF and reel conveyance vehicle VR and the like from traveling control section 25.

Here, as traveling device 20, for example, an automatic guided vehicle (AGV) can be used. In this case, traveling device 20 is provided with a tape detection section that detects a path display tape (refer to FIG. 1), which is provided on the floor surface of production line PL to correspond to the conveyance path and the conveyance target, and that outputs the detection result to traveling control section 25. Consequently, traveling control section 25 controls a control amount of drive wheels 22 (the traveling motor) in accordance with the detection result output from the tape detection section and causes traveling device 20 to travel along the conveyance path or to stop at the conveyance target. The tape detection section is disposed at a front position and a rear position in the front-rear direction on the center line on the underside of device main body 21. Additionally, a magnetic display tape or an optical display tape can be used as the path display tape.

As mentioned above, traveling device 20 autonomously travels under the control of traveling control section 25. In addition, by operating operation panel 26 disposed at the rear part of the upper surface of device main body 21, the manual operation for some of the operations of traveling device 20 is possible. Specifically, by operating operation panel 26, for example, in a case of a stop due to an error related to the traveling of traveling device 20 (for example, an abnormality such as path deviation or stop position deviation), that is, in a case of a so-called error stop, it is possible to release the error or perform an emergency stop of traveling device 20.

### 2-5. Detection Section 30

Detection section 30 detects that feeder F (reel R or the like) that is an article has been attached or detached with respect to magazine M (rack T or the like) that is a case placed on the support section of cart 10, that is, loading/unloading section 17, in the conveyance of conveyance object C. Specifically, as shown in FIGS. 2 and 3, detection section 30 of the present embodiment is disposed on the upper surface of loading platform 11 on the rear side in the front-rear direction of cart 10.

More specifically, as shown in FIG. 2, detection section 30 of the present embodiment is disposed on the upper surface of loading platform 11 to be located in the vicinity of opening portion M1 of magazine M supported by loading/unloading section 17. As a result, detection section 30 of the present embodiment detects the presence or absence state of feeder F that is an article at opening portion M1 of magazine M, that is, detects that feeder F has been inserted or removed (the article has been attached or detached) through opening portion M1.

Then, as shown in FIG. 4, in a case where detection section 30 detects that feeder F has been inserted into or removed from magazine M, detection section 30 outputs detection result S to determination section 161 of cart control section 16. As a result, in a case where detection section 30 detects the presence of feeder F at opening portion M1, determination section 161 determines that the insertion or removal (attachment or detachment) of feeder F has been performed.

Detection section 30 detects the insertion or removal of feeder F that is an article, based on an electromagnetically measurable physical quantity. Therefore, in the present embodiment, for example, detection section 30 including a photoelectric sensor using light that is an electromagnetic wave is exemplified.

As shown in FIGS. 2 and 3, detection section 30 of the present embodiment includes light emitting section 31 and light receiving section 32. As a result, in a case where the light emitted from light emitting section 31 toward light receiving section 32 is received by light receiving section 32, since the emitted light is not obstructed, that is, since feeder F is not present at opening portion M1 and no insertion or removal of feeder F is performed, detection section 30 does not output detection result S.

On the other hand, in a case where the light emitted from light emitting section 31 toward light receiving section 32 is not received by light receiving section 32, or in a case where the light is not received by light receiving section 32 for a light shading time that can be set in advance based on the time required for the insertion or removal of feeder F, since the emitted light is obstructed, that is, since feeder F is present at opening portion M1 and the insertion or removal of feeder F is performed, detection section 30 outputs detection result S. A situation in which light receiving section 32 cannot receive light beyond the light shading time is assumed to occur due to, for example, issues such as accommodation failure of feeder F with respect to magazine M (such as deviation of feeder F) caused by vibrations in the traveling (movement) of feeder conveyance vehicle VF). In this case, detection section 30 also outputs detection result S to cart control section 16.

Here, determination section 161 determines that the attachment or detachment of feeder F has been completed in a case where the detection of the presence of feeder F by detection section 30 does not continue for a predetermined time (for example, the light shading time that can be appropriately set as mentioned above) or longer after determining that the insertion or removal (attachment or detachment) of feeder F has been performed. Cart control section 16 and traveling control section 25 cooperate with each other to continue the conveyance of conveyance object C in a case where determination section 161 determines that the insertion or removal (attachment or detachment) of feeder F has been completed.

On the other hand, determination section 161 determines that the attachment or detachment of feeder F is not completed, for example, in a case where the detection of the presence of feeder F by detection section 30 continues for the predetermined time or longer due to the deviation of feeder F mentioned above or the like. Cart control section 16 and traveling control section 25 cooperate with each other to stop the conveyance of conveyance object C in a case where determination section 161 determines that the insertion or removal (attachment or detachment) of feeder F is not completed. As a result, it is possible to prevent feeder F from falling out of magazine M during conveyance by feeder conveyance vehicle VF.

Additionally, in a case where determination section 161 determines that the insertion or removal of feeder F has been performed, as shown in FIG. 4, cart control section 16 outputs notification information J indicating that the insertion or removal of feeder F has been performed in the conveyance to management device 8 installed outside through communication. That is, in a case where determination section 161 determines the attachment or detachment of feeder F that is an article in the conveyance of conveyance object C, cart control section 16 can output notification information J regarding the insertion or removal (attachment or detachment) of feeder F to management device 8.

Here, in a case where management device 8 acquires notification information J from cart control section 16 of feeder conveyance vehicle VF, management device 8 provides a notification (or warning) to the worker, the manager, or the like using a notification device. That is, the notification device notifies that feeder F has been inserted into or removed from magazine M, for example, during the conveyance to buffer station 5 by feeder conveyance vehicle VF. Examples of the notification device include a display device provided in management device 8, a display device provided on production line PL, a mobile terminal carried by the worker, and a voice speaker.

As can be understood from the above description, feeder conveyance vehicle VF (reel conveyance vehicle VR) as the autonomous conveyance vehicle of the present embodiment is an autonomous conveyance vehicle capable of conveying conveyance object C including feeder F (reel R) as an article used in buffer station 5 and component mounter 6 that are board work machines and magazine M (rack T) as a case that detachably holds feeder F (reel R), the autonomous conveyance vehicle including cart 10 that is the main body, loading/unloading section 17 as the support section that is provided in cart 10 and supports magazine M (rack T), detection section 30 that is provided in cart 10 and detects the presence or absence state of feeder F (reel R) with respect to magazine M (rack T) in the conveyance of conveyance object C, and determination section 161 that determines whether feeder F (reel R) has been attached to or detached from (inserted into or removed from) magazine M (rack T) based on detection result S by detection section 30.

With feeder conveyance vehicle VF and reel conveyance vehicle VR, detection section 30 can promptly detect the insertion or removal of feeder F into or from magazine M and the attachment or detachment of reel R to or from rack T in the conveyance of conveyance object C. With feeder conveyance vehicle VF and reel conveyance vehicle VR, in a case where determination section 161 determines that feeder F has been inserted into or removed from magazine M and reel R has been attached to or detached from rack T based on detection result S by detection section 30, notification information J can be output to management device 8 and the like, and the worker, the manager, or the like can be promptly notified. As a result, for example, even in a case where feeder F has been inserted into or removed from magazine M and reel R has been attached to or detached from rack T in the conveyance of conveyance object C, it is possible to suppress the occurrence of shortage or the like of components necessary for production, thereby minimizing the impact on production.

### 3. First Modification Example

In the above-mentioned embodiment, a case has been exemplified in which detection section 30 detects the presence or absence state of feeder F that is an article at opening portion M1 of magazine M that is a case supported by loading platform 11 of cart 10. In this case, determination section 161 determines that the insertion or removal of feeder F has been performed through opening portion M1 of magazine M in the conveyance of conveyance object C by feeder conveyance vehicle VF that is an autonomous conveyance vehicle. As a result, cart control section 16 can output notification information J to management device 8.

Meanwhile, in a case where the insertion or removal of feeder F that is not included in the conveyance plan including the attachment or detachment of feeder F (reel R) to or from magazine M (rack T) set in advance and the attachment or detachment of magazine M (rack T) to or from loading/unloading section 17 has been performed, it is preferable that inserted or removed feeder F can be specified. That is, in a case where the insertion or removal of feeder F that is not included in the conveyance plan, that is, unintended feeder F, has been performed, it is preferable that inserted or removed feeder F, that is, the component predicted to be in shortage, can be specified, for example, from the viewpoint of reducing the impact on production due to the shortage of the component. Specifically, since the position of feeder F to be accommodated in magazine M is set in advance by the conveyance plan, it is preferable that the position of inserted or removed feeder F with respect to magazine M can be detected.

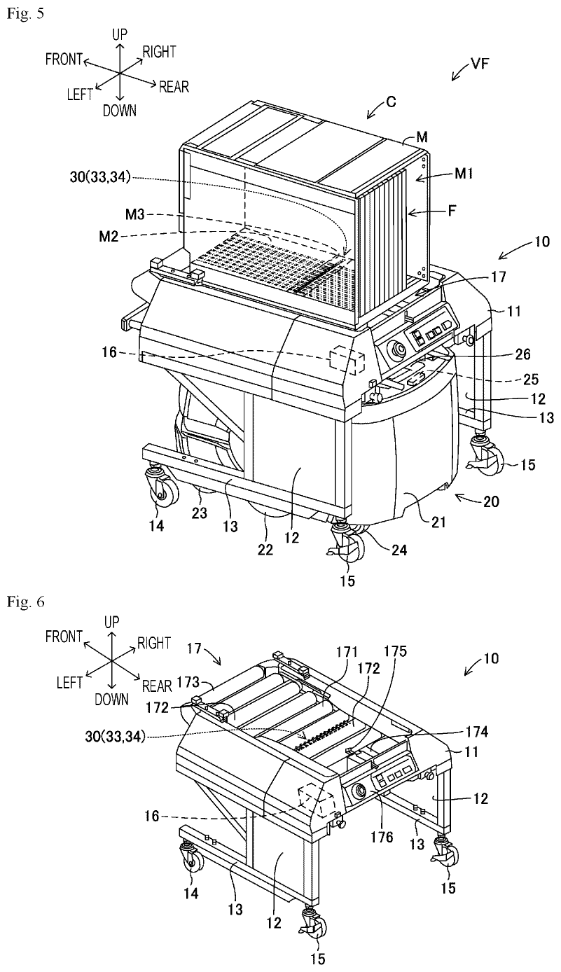

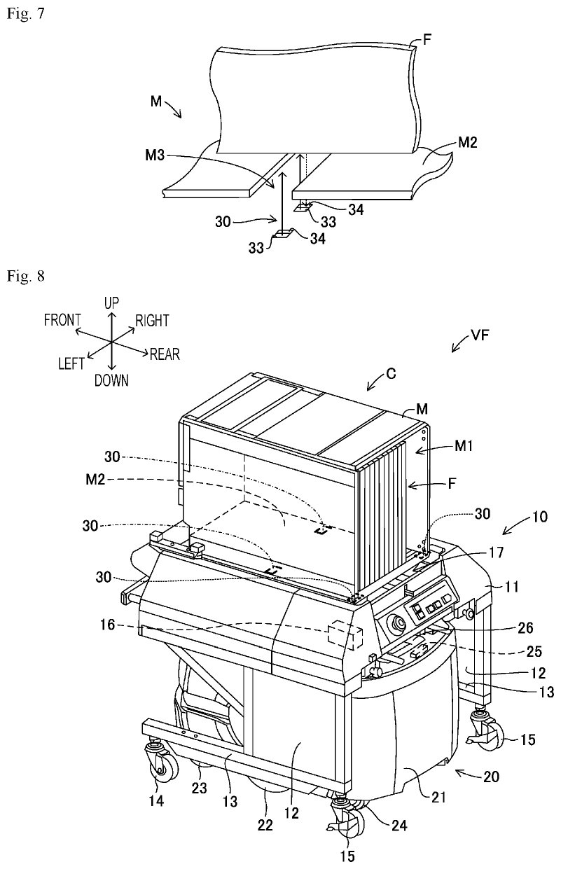

In this regard, in the first modification example, as shown in FIG. 5, detection section 30 is disposed on loading platform 11 of cart 10 to be located below feeder F that is an article, through slit M3 that is a gap provided in bottom surface M2 of magazine M, which is a case supported by loading/unloading section 17 that is a support section (also refer to FIG. 7). More specifically, as shown in FIG. 6, detection section 30 of the first modification example is disposed on the lower side of drive roller 172, which is located on the rear side with respect to main roller 171 of loading/unloading section 17, and is disposed to align with the formation position of slit M3 in a state in which magazine M is supported, for example, to match the gap between drive rollers 172 formed in the front-rear direction.

Multiple detection sections 30 of the first modification example are disposed in accordance with the widths (pitches) of feeders F accommodated in magazine M in order to detect the presence or absence state of feeders F with respect to magazine M. That is, detection section 30 of the first modification example is provided in a one-to-one relationship with feeder F accommodated in magazine M.

Similarly to detection section 30 of the embodiment mentioned above, detection section 30 of the first modification example also includes a photoelectric sensor using light that is an electromagnetic wave. However, as shown in FIG. 7 in an enlarged manner, detection sections 30 of the first modification example each includes light emitting section 33 and light receiving section 34. Consequently, in detection section 30 disposed at a position where feeder F is accommodated in magazine M, when light emitting section 33 emits light upward, the light is reflected on the lower surface of accommodated feeder F (that is, present inside magazine M), and the reflected light is received by light receiving section 34. On the other hand, in detection section 30 disposed at a position where feeder F is not accommodated in magazine M (that is, feeder F is not present inside magazine M), no reflected light is generated even when light emitting section 33 emits light upward, and light receiving section 34 consequently does not receive reflected light.

Therefore, for example, in a case where a state in which light receiving section 34 of detection section 30 receives the reflected light is changed to a state in which light receiving section 34 cannot receive the reflected light, in the conveyance of conveyance object C by feeder conveyance vehicle VF, determination section 161 of the first modification example outputs detection result S because feeder F has been detached (removed) from magazine M. In addition, for example, in a case where a state in which light receiving section 34 does not receive the reflected light is changed to a state in which light receiving section 34 receives the reflected light, determination section 161 outputs detection result S because feeder F has been accommodated (inserted) in magazine M. Here, in the first modification example, detection section 30 outputs detection result S in association with identification information (an identification number or the like) for identifying detection section 30.

Additionally, for example, in a case where a state in which light receiving section 34 receives the reflected light does not change until loading or unloading is performed at the delivery position (conveyance target) in the conveyance plan, in the conveyance of conveyance object C by feeder conveyance vehicle VF, determination section 161 of the first modification example does not output detection result S because feeder F is not detached (not removed) from magazine M. Further, for example, in a case where a state in which light receiving section 34 does not receive the reflected light does not change until loading or unloading is performed at the delivery position (conveyance target), determination section 161 does not output detection result S because feeder F is not accommodated in (not inserted into) magazine M.

That is, determination section 161 of the first modification example determines that the insertion or removal (attachment or detachment) of feeder F has been performed based on the switching of the presence or absence state of feeder F detected by detection section 30, specifically, the change in detection result S occurring in a state in which light receiving section 34 receives the reflected light or a state in which light receiving section 34 does not receive the reflected light. In the first modification example, in a case where determination section 161 determines the insertion or removal (attachment or detachment) of feeder F based on detection result S by detection section 30, cart control section 16 outputs notification information J indicating that the insertion or removal of feeder F has been performed in the conveyance of conveyance object C and the identification information (identification number) of detection section 30 for specifying inserted or removed feeder F to management device 8 through communication. That is, in a case where detection section 30 of the first modification example detects the attachment or detachment of feeder F that is an article in the conveyance of conveyance object C, the fact that the insertion or removal (attachment or detachment) has been performed and the position of feeder F which is the inserted or removed (attached or detached) article with respect to magazine M as notification information J regarding the insertion or removal (attachment or detachment) of detected feeder F can be output to management device 8.

Here, in the first modification example, in a case where management device 8 acquires notification information J from cart control section 16 of feeder conveyance vehicle VF, management device 8 also provides a notification (or warning) to the worker, the manager, or the like using the notification device. However, in the first modification example, for example, during the conveyance to buffer station 5 by feeder conveyance vehicle VF, in addition to the notification about the insertion or removal of feeder F into or from magazine M, the notification about the position of feeder F accommodated in (inserted into) or detached (removed) from magazine M is also provided. Therefore, in the first modification example, in addition to obtaining the same effect as that of the embodiment mentioned above, it is possible to detect the position of inserted or removed feeder F (the position of the attached or detached article). As a result, for example, the worker, the manager, or the like can quickly specify the component that is predicted to be in shortage, consequently enabling faster responses such as replenishment, thereby further reducing the impact on production.

### 4. Second Modification Example

In the embodiment mentioned above and the first modification example mentioned above, a case has been exemplified in which detection section 30 detects the insertion or removal (attachment or detachment) of feeder F that is an article based on an electromagnetically measurable physical quantity. Meanwhile, when feeder F accommodated in magazine M that is a case or reel R placed on rack T is inserted or removed (attached or detached), the state of magazine M or rack T changes.

For example, feeder F and reel R have a certain weight. Therefore, when feeder F is inserted into or removed from magazine M, the weight of magazine M supported by loading/unloading section 17 that is a support section and the weight of feeder F accommodated in magazine M, that is, the weight of conveyance object C, change. Similarly, when reel R is attached or detached with respect to rack T, the weight of rack T is supported by loading/unloading section 17 and the weight of reel R placed on rack T, that is, the weight of conveyance object C, change.

In this regard, in the second modification example, detection section 30 detects a measurable physical quantity in relation to a state change of magazine M or rack T which is a case. Then, determination section 161 determines the attachment or detachment (insertion or removal) of feeder F or reel R, which is an article, based on a change in the physical quantity detected by detection section 30. Specifically, detection section 30 of the second modification example measures, as the physical quantity, the weight of magazine M or rack T, which is a case that changes when feeder F or reel R has been attached or detached (inserted or removed), that is, the weight of conveyance object C.

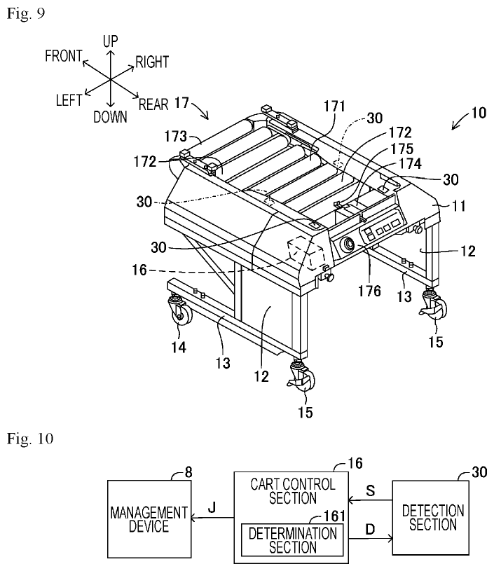

In the second modification example, as shown in FIG. 8, detection section 30 is provided on loading platform 11 of cart 10 to be located on the underside of magazine M or rack T that is a case supported by loading/unloading section 17 that is a support section. More specifically, as shown in FIG. 9, detection section 30 of the second modification example is disposed on the rear side of loading platform 11 in the front-rear direction and is disposed between the lower surface of supported magazine M or rack T and the upper surface of loading platform 11, that is, disposed to be sandwiched between the lower surface of magazine M or rack T and the upper surface of loading platform 11.

Detection section 30 of the second modification example measures the measurable weight in relation to the state change of magazine M or rack T, as mentioned above. Here, detection section 30 of the second modification example includes a piezoelectric element that converts a pressure generated when sandwiched between magazine M or rack T and loading platform 11 into an electrical signal. The pressure converted into the electrical signal and output can be easily converted into the weight by multiplying the area of the lower surface of magazine M or rack T.

In a case where detection section 30 measures the weight using the piezoelectric element, magazine M or rack T supported by loading/unloading section 17 is not displaced in the up-down direction. Consequently, even in the second modification example in which detection section 30 measures the weight of conveyance object C, there is no interference with the loading/unloading operation of magazine M or rack T by loading/unloading section 17. In a case of measuring the weight of conveyance object C, for example, when using a typical weight scale or the like, conveyance object C supported by loading/unloading section 17 needs to be displaced in the up-down direction during the measurement of the weight. Therefore, for example, when loading/unloading section 17 loads or unloads magazine M or rack T at buffer station 5, a difference between the height of loading/unloading section 17 and the height of buffer station 5 may occur, which may result in an inability to perform the loading or unloading and lead to an error stop.

Determination section 161 of the second modification example determines that, for example, in a case where the measured weight increases or decreases to a reference weight or more with respect to the reference weight determined based on the weight of one feeder F or reel R, in the conveyance of conveyance object C by feeder conveyance vehicle VF, feeder F or reel R has been attached or detached (inserted or removed). In addition, determination section 161 of the second modification example determines that feeder F or reel R has not been attached or detached (inserted or removed) in a case where the measured weight does not change until loading or unloading is performed at the delivery position (conveyance target) in the conveyance of conveyance object C by feeder conveyance vehicle VF. As shown in FIG. 9, in a case where detection section 30 is disposed on the left and right sides, it can be assumed that the insertion or removal of feeder F has been performed particularly on the right side or the left side with respect to magazine M, even if it is not possible to specify an exact position.

Consequently, in the second modification example, in a case where determination section 161 determines that the attachment or detachment (insertion or removal) of feeder F (reel R) has been performed based on detection result S by detection section 30, cart control section 16 also outputs notification information J indicating that the attachment or detachment (insertion or removal) of feeder For reel R has been performed in the conveyance of conveyance object C to management device 8 through communication. Here, in the second modification example, in a case where management device 8 acquires notification information J from cart control section 16 of feeder conveyance vehicle VF, management device 8 also provides a notification (or warning) to the worker, the manager, or the like using the guidance device. That is, in the second modification example, for example, the fact that feeder F has been inserted into or removed from magazine M is also notified during the conveyance to buffer station 5 by feeder conveyance vehicle VF. Accordingly, in the second modification example, the same effect as that of the embodiment mentioned above can also be obtained.

In the second modification example mentioned above, two detection sections 30 are provided, thereby enabling, for example, the detection of weight changes on the left and right sides of magazine M or the averaging of the detected weight. However, the number of detection sections 30 of the second modification example is not limited and may be one or three or more. Additionally, in the second modification example mentioned above, as shown in FIG. 9, detection section 30 is disposed on the rear side of loading platform 11 in the front-rear direction. However, the disposition of detection section 30 of the second modification example is not limited to the rear side of loading platform 11 in the front-rear direction, and detection section 30 can also be disposed at the center of loading platform 11 in the front-rear direction as indicated by a one-dot chain line in FIGS. 8 and 9. That is, the disposition of detection section 30 can be appropriately changed based on the shape of magazine M or rack T.

### 5. Third Modification Example

In the embodiment mentioned above, the first modification example mentioned above, and the second modification example mentioned above, a case has been exemplified in which detection section 30 always detects the presence or absence state of feeder F or reel R that is an article when magazine M or rack T that is conveyance object C is conveyed, and determination section 161 always determines whether the attachment or detachment (insertion or removal) of feeder F or reel R has been performed. However, detection section 30 and determination section 161 are not limited to always detecting the presence or absence state of feeder F or reel R that is an article and always determining whether the attachment or detachment (insertion or removal) has been performed as mentioned above. That is, for example, in a case where a predetermined state has occurred, detection section 30 and determination section 161 can also detect the presence or absence state of feeder F or reel R and determine whether the attachment or detachment (insertion or removal) has been performed. Hereinafter, a third modification example will be described.

Detection section 30 of the third modification example detects the presence or absence state of feeder F or reel R in a case where the predetermined state has occurred in the conveyance of conveyance object C. In addition, determination section 161 of the third modification example determines whether the attachment or detachment (insertion or removal) of feeder F or reel R has been performed in a case where a predetermined state has occurred in the conveyance of conveyance object C. Here, in the third modification example, as shown in FIG. 10, in a case where the predetermined state has occurred, determination section 161 outputs detection command D for causing detection section 30 to detect the presence or absence state of the article, specifically, the presence or absence state of feeder F (reel R) with respect to magazine M (rack T).

Here, examples of the predetermined state include a state in which the attachment or detachment (insertion or removal) of feeder F or reel R that is not included in the conveyance plan mentioned above, that is, unintended feeder F or reel R, is possible. Specifically, for example, in a state in which feeder conveyance vehicle VF and reel conveyance vehicle VR are unintentionally stopped at a place other than the conveyance target on the conveyance path, feeder F or reel R is easily attached to or detached from (inserted into or removed from) magazine M or rack T as compared with a state in which feeder conveyance vehicle VF or reel conveyance vehicle VR travel (move).

Therefore, for example, determination section 161 outputs detection command D to detection section 30 at a predetermined position on the conveyance path in the conveyance of conveyance object C or at a periodic timing in the conveyance of conveyance object C. Consequently, detection section 30 detects the presence or absence state of feeder F or reel R at the predetermined position on the conveyance path or at the periodic timing and outputs detection result S to determination section 161 (cart control section 16). Then, determination section 161 determines the attachment or detachment (insertion or removal) of feeder F or reel R based on obtained detection result S at the predetermined position on the conveyance path or at the periodic timing. Cart control section 16 including determination section 161 grasps the conveyance plan set in advance and grasps the state of feeder conveyance vehicle VF or reel conveyance vehicle VR based on various information obtained from traveling control section 25.

Here, in the third modification example, a case will be exemplified in which detection section 30 detects the presence or absence state of feeder F or reel R at the predetermined position on the conveyance path or at the periodic timing, and determination section 161 determines the attachment or detachment (insertion or removal) of feeder F or reel R. However, for example, detection section 30 may always detect the presence or absence state of feeder F or reel R in the conveyance of conveyance object C, and only determination section 161 may determine the attachment or detachment (insertion or removal) of feeder F or reel R at the predetermined position on the conveyance path or at the periodic timing. That is, in this case, determination section 161 does not output detection command D to detection section 30.

Alternatively, determination section 161 may always determine the attachment or detachment (insertion or removal) of feeder F or reel R in the conveyance of conveyance object C based on, for example, detection result S that does not change for a certain period of time, and only detection section 30 may detect the presence or absence state of feeder F or reel R at the predetermined position on the conveyance path or at the periodic timing. That is, in this case, in a case where detection command D is output to detection section 30 at the predetermined position or at the periodic timing, determination section 161 determines the attachment or detachment (insertion or removal) of feeder F or reel R based on updated detection result S.

Additionally, examples of the predetermined state include a state of recovery after an abnormality (error) as mentioned above occurs in the conveyance of conveyance object C. In this case, determination section 161 determines the attachment or detachment (insertion or removal) of feeder F or reel R that is an article, more specifically, as the predetermined state, in a first state in which an abnormality (error) has occurred and a second state in which the recovery of the abnormality (error) has been performed. The signals such as the error stop are aggregated in cart control section 16.

Determination section 161 outputs detection command D to detection section 30, for example, in a case where cart control section 16 determines that the first state has occurred. Consequently, determination section 161 determines the attachment or detachment (insertion or removal) of the article such as feeder F or reel R based on a state in which an abnormality (error) has occurred, in other words, detection result S before recovery from the abnormality (error). In addition, determination section 161 outputs detection command D to detection section 30, for example, in a case where cart control section 16 determines that the second state has occurred. As a result, determination section 161 determines the attachment or detachment (insertion or removal) of the article such as feeder F or reel R based on detection result S after recovery from the abnormality (error).

That is, determination section 161 outputs detection command D to detection section 30 in a case where the first state in which an abnormality (error) has occurred and the second state in which the recovery of the abnormality (error) has been performed have occurred, that is, before and after recovery from the abnormality (error) as the predetermined state. As a result, determination section 161 determines the attachment or detachment (insertion or removal) of the article such as feeder F or reel R based on a change in detection result S of detection section 30 before and after recovery from the abnormality (error).

Further, examples of the predetermined state include a state in which conveyance object C is delivered. In this case, determination section 161 determines the attachment or detachment (insertion or removal) of feeder For reel R that is an article, more specifically, as the predetermined state, in a third state before conveyance object C is delivered from feeder conveyance vehicle VF or reel conveyance vehicle VR to buffer station 5 and a fourth state after conveyance object C is delivered from buffer station 5 to feeder conveyance vehicle VF or reel conveyance vehicle VR. As mentioned above, cart control section 16 controls the loading or unloading of conveyance object C by loading/unloading section 17, that is, the delivery of conveyance object C with respect to the board work machine.

Determination section 161 outputs detection command D to detection section 30, for example, in a case where cart control section 16 determines that the third state has occurred. Consequently, determination section 161 determines the attachment or detachment (insertion or removal) of the article such as feeder F or reel R based on detection result S before the delivery of conveyance object C. Additionally, determination section 161 outputs detection command D to detection section 30, for example, in a case where cart control section 16 determines that the fourth state has occurred. As a result, determination section 161 detects the attachment or detachment (insertion or removal) of the article such as feeder F or reel R based on detection result S after the delivery of conveyance object C.

That is, determination section 161 outputs detection command D to detection section 30 in a case where the third state before the delivery of conveyance object C and the fourth state after the delivery of conveyance object C have occurred, that is, before and after the delivery of conveyance object C as the predetermined state. As a result, detection section 30 detects the presence or absence state of feeder F with respect to magazine M or the presence or absence state of reel R with respect to rack T before and after the delivery of conveyance object C, and determination section 161 determines the attachment or detachment (insertion or removal) of the article such as feeder F or reel R based on a change in detection result S of detection section 30 before and after the delivery of conveyance object C.

Therefore, in the third modification example, it is possible to focus on determining, in other words, monitoring, the attachment or detachment (insertion or removal) of feeder F or reel R, particularly in the predetermined state in which the attachment or detachment (insertion or removal) of feeder F or reel R is likely to occur. As for other effects, the same effects as those of the embodiment, the first modification example, and the second modification example mentioned above can be obtained.

### REFERENCE SIGNS LIST

1: Warehouse, 1a: Entry/exit, 2: Off-line setup area, 3: Tape automatic processing device, 4: Reel loading device, 5: Buffer station (board work machine), 6: Component mounter (board work machine), 7: Loader, 8: Management device, 10: Cart (main body), 11: Loading platform, 12: Side surface portion, 13: Leg portion, 14: Front wheel, 15: Rear wheel, 16: Cart control section, 161: Determination section, 17: Loading/unloading section (support section), 171: Main roller, 172: Drive roller, 173: Guide roller, 174: Locking mechanism, 175: Locking hook, 176: Operation panel, 20: Traveling device, 21: Device main body, 22: Drive wheel, 23: Front wheel, 24: Rear wheel, 25: Traveling control section, 26: Operation panel, 30: Detection section, 31: Light emitting section, 32: Light receiving section, 33: Light emitting section, 34: Light receiving section, S: Production line, VR: Reel conveyance vehicle (autonomous conveyance vehicle), VF: Feeder conveyance vehicle (autonomous conveyance vehicle), C: Conveyance object, T: Rack (case), R: Tape reel (article), M: Magazine (case), F: Tape feeder (article), S: Detection result, J: Notification information, D: Detection command

1. An autonomous conveyance vehicle capable of conveying a conveyance object including an article used in a board work machine and a case configured to detachably hold the article, the autonomous conveyance vehicle comprising:
a main body;
a support section provided on the main body and configured to support the case;
a detection section provided on the main body and configured to detect a presence or absence state of the article with respect to the case in conveyance of the conveyance object; and
a determination section configured to determine whether attachment or detachment of the article with respect to the case has been performed based on a detection result by the detection section.

2. The autonomous conveyance vehicle according to claim 1, wherein
the detection section detects the presence or absence state of the article at an opening portion for attaching or detaching the article to and from the case supported by the support section, and
the determination section determines that the attachment or detachment of the article has been performed in a case where the detection section detects presence of the article.

3. The autonomous conveyance vehicle according to claim 2, wherein the determination section determines that the attachment or detachment of the article has been completed in a case where detection of the presence of the article by the detection section does not continue for a predetermined time or longer after determining that the attachment or detachment of the article has been performed, and determines that the attachment or detachment of the article is not completed in a case where the detection of the presence of the article by the detection section continues for the predetermined time or longer.

4. The autonomous conveyance vehicle according to claim 2, wherein the conveyance of the conveyance object continues in a case where the determination section determines that the attachment or detachment of the article has been completed, and the conveyance of the conveyance object is stopped in a case where the determination section determines that the attachment or detachment of the article is not completed.

5. The autonomous conveyance vehicle according to claim 1, wherein
the detection section is disposed below the article through a slit provided in a bottom surface of the case supported by the support section and detects the presence or absence state of the article, and
the determination section determines that the attachment or detachment of the article has been performed based on switching of the presence or absence state of the article by the detection section.

6. The autonomous conveyance vehicle according to claim 5, wherein the detection section detects a position where the article has been attached or detached with respect to the case.

7. The autonomous conveyance vehicle according to claim 1, wherein the detection section detects a measurable physical quantity in relation to a state change of the case, and
the determination section determines the attachment or detachment of the article based on a change in the physical quantity detected by the detection section.

8. The autonomous conveyance vehicle according to claim 7, wherein the physical quantity is a weight of the conveyance object.

9. The autonomous conveyance vehicle according to claim 1, wherein in a case where the determination section determines that the attachment or detachment of the article has been performed, notification information regarding the attachment or detachment of the article is output to a management device configured to manage the conveyance of the conveyance object.

10. The autonomous conveyance vehicle according to claim 1, wherein the determination section determines attachment or detachment of an article that is not included in a conveyance plan including attachment or detachment of the article with respect to a case set in advance and attachment or detachment of the case with respect to the support section.

11. The autonomous conveyance vehicle according to claim 10, wherein at least one of detection of the presence or absence state of the article by the detection section and determination of the attachment or detachment of the article by the determination section is performed at a predetermined position in the conveyance of the conveyance object or at a periodic timing in the conveyance of the conveyance object.

12. The autonomous conveyance vehicle according to claim 10, wherein the determination section determines, in a case where an abnormality has occurred in the conveyance of the conveyance object, the attachment or detachment of the article based on a change in the detection result of the detection section before and after recovery from the abnormality.

13. The autonomous conveyance vehicle according to claim 1, wherein the detection section detects the presence or absence state of the article with respect to the case before and after delivery of the conveyance object.

14. The autonomous conveyance vehicle according to claim 1, wherein
the article is a feeder configured to supply a component to the board work machine,
the case is a magazine into which multiple feeders are insertable and removable, and
the detection section detects insertion or removal of the feeder to or from the magazine in the conveyance of the conveyance object.
